(19) United States
(12) Patent Application Publication
(10) Pub. No.: US 2025/0345896 A1
(43) Pub. Date: Nov. 13, 2025

(54) Polishing Pad for Chemical Mechanical Polishing and Method

(71) Applicant: Taiwan Semiconductor Manufacturing Co., Ltd., Hsinchu (TW)

(72) Inventors: Te-Chien Hou, Kaohsiung City (TW); Chih Hung Chen, Hsinchu (TW); Liang-Che Chen, Hsinchu (TW); Shich-Chang Suen, Hsinchu (TW); Liang-Guang Chen, Hsinchu (TW)

(21) Appl. No.: 19/277,958

(22) Filed: Jul. 23, 2025

Related U.S. Application Data
(63) Continuation of application No. 17/822,867, filed on Aug. 29, 2022.
(60) Provisional application No. 63/366,075, filed on Jun. 9, 2022.

(51) Int. Cl. B24D 3/00; B24B 7/22; H01L 21/304

(52) U.S. Cl. CPC B24D 3/00; B24B 7/228; H01L 21/304

(57) ABSTRACT

Polishing pads having varying protrusions and methods of forming the same are disclosed. In an embodiment, a polishing pad includes a polishing pad substrate; a first protrusion on the polishing pad substrate, the first protrusion including a central region and a peripheral region surrounding the central region, and a first hardness of the central region being greater than a second hardness of the peripheral region; and a first groove adjacent a first side of the first protrusion.

### PRIORITY CLAIM AND CROSS-REFERENCE

This application is a continuation of U.S. patent application Ser. No. 17/822,867, filed on Aug. 29, 2022, which claims the benefit of U.S. Provisional Patent Application No. 63/366,075, filed on Jun. 9, 2022, each application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon. The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a wafer to be polished, in accordance with some embodiments.

FIG. 2 illustrates a perspective view of a chemical mechanical polishing (CMP) apparatus, in accordance with some embodiments.

FIG. 3 illustrates a top-down view of a CMP apparatus, in accordance with some embodiments.

FIG. 4 illustrates a cross-sectional view of a polisher head on a polishing pad, in accordance with some embodiments.

FIGS. 5, 6, 7, 8, 9, 10, 11, 12, 13, 14, 15, and 16 illustrate cross-sectional views of polishing pads, in accordance with some embodiments.

FIGS. 17, 18, 19, 20, and 21 illustrate top-down views of polishing pads, in accordance with some embodiments.

FIG. 22 illustrates a cross-sectional view of an additive manufacturing process, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide improved polishing pads that may be used in chemical mechanical polishing (CMP) or other polishing or planarizing processes, and methods of forming the same. In some embodiments, a polishing pad may include protrusions formed on a bulk substrate and grooves on the bulk substrate adjacent the protrusions. Each of the protrusions may be formed of multiple materials. For example, the central portions of the protrusions may be formed of a first material, and peripheral portions of the protrusions may be formed of a second material. A hardness of the first material may be different from a hardness of the second material. In some embodiments, the second material has a hardness less than a hardness of the first material, and a compressibility greater than the first material. This may be achieved by using different materials for the first material and the second material, providing pores of different sizes in the first material and the second material, or by providing different densities of pores in the first material and the second material. In some embodiments, the widths, heights, and/or spacing of the protrusions may vary across the surface of the bulk substrate. Forming polishing pads with multi-material protrusions and/or protrusions with varying widths, heights, and/or spacing improves the processing of semiconductor wafers by the polishing pads, which reduces device defects in the semiconductor wafers and improves device performance for devices formed on the semiconductor wafers. Specifically, the polishing pads feature reduced scratching of the semiconductor wafers, improved distribution of polishing chemicals across the polishing pads, reduced consumption of the polishing chemicals, improved wafer-to-wafer and within-wafer uniformity, and the capability of applying a more even down-force to the semiconductor wafers during processing.

Chemical mechanical polishing (or planarization) (CMP) is one method of planarizing features produced in the manufacture of semiconductor devices. The process uses an abrasive material and a reactive chemical slurry in conjunction with a polishing pad. The polishing pad typically has a greater diameter than that of a semiconductor wafer polished by the polishing pad. The polishing pad and the semiconductor wafer are pressed together by operation of dynamic polishing heads. The dynamic polishing heads may be rotated around different axes of rotation (e.g., non-concentric axes). The process removes material from the semiconductor wafer and evens out irregular topography on the semiconductor wafer, making the semiconductor wafer flat or substantially planar. This prepares the semiconductor wafer for the formation of additional overlying circuit elements. In some embodiments, CMP can bring an entire surface of a semiconductor wafer within a given depth of field for a photolithography system. Typical depth-of-field specifications are on the order of angstroms. In some embodiments, CMP may be employed to selectively remove material based on its location on the semiconductor wafer.

Generally, CMP is performed by placing a semiconductor wafer in a carrier head, where the semiconductor wafer is held in place by a retaining ring. The carrier head and the semiconductor wafer are then rotated as a downward pressure is applied to the semiconductor wafer to press the semiconductor wafer against a polishing pad. A reactive chemical solution (e.g., a CMP slurry) is dispensed on a contacting surface of the polishing pad to aid the polishing. The surface of the semiconductor wafer may thus be polished and planarized using a combination of mechanical and chemical mechanisms.

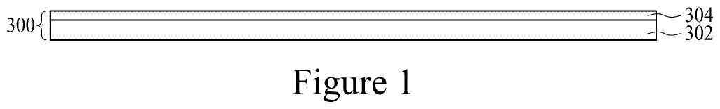

FIG. 1 illustrates a semiconductor wafer 300 that will be polished with a chemical mechanical polishing (CMP) apparatus. In some embodiments, the wafer 300 includes a semiconductor substrate 302 (e.g., including silicon, a III-V semiconductor material, or the like), active devices (e.g., transistors, or the like) on the semiconductor substrate 302, and/or various interconnect structures on the active devices and the semiconductor substrate 302. The interconnect structures may include conductive features, which electrically connect the active devices in order to form functional circuits. In some embodiments, chemical mechanical polishing may be applied to the wafer 300 during any stage of manufacture in order to planarize features or otherwise remove undesired material (e.g., dielectric material, semiconductor material, conductive material, or the like) from the wafer 300. The wafer 300 may include any subset of the above-identified features, as well as other features.

As illustrated in FIG. 1, the wafer 300 may include a layer to be polished 304 on the semiconductor substrate 302. The layer to be polished 304 may be a layer that has been deposited and is now desired to polished (e.g., planarized) in preparation for further manufacturing. In some embodiments in which the layer to be polished 304 includes tungsten, the layer to be polished 304 may be polished to form contact plugs contacting various active devices or features of the wafer 300. In embodiments in which the layer to be polished 304 includes copper, the layer to be polished 304 may be polished to form various interconnect structures (e.g., conductive line, conductive vias, or the like) of the wafer 300. In embodiments in which the layer to be polished 304 includes a dielectric material, the layer to be polished 304 may be polished to form shallow trench isolation (STI) structures, interlayer dielectric (ILD) structures, inter-metal dielectric (IMD) structures, or the like on the wafer 300. The layer to be polished 304 may be any suitable layer and any suitable material processed during the manufacturing of the wafer 300.

In some embodiments, the layer to be polished 304 may have a non-uniform thickness (e.g., exhibiting local or global topological variation of an exposed surface of the layer to be polished 304) resulting from underlying structures and process variations experienced during deposition of the layer to be polished 304. For example, in an embodiment in which the layer to be polished 304 includes tungsten, the layer to be polished 304 may be formed by depositing tungsten into an opening through a dielectric layer using a chemical vapor deposition (CVD) process. Due to CVD process variations, the shapes of underlying structures, and the like, the layer to be polished 304 may have a non-uniform thickness and a non-planar surface.

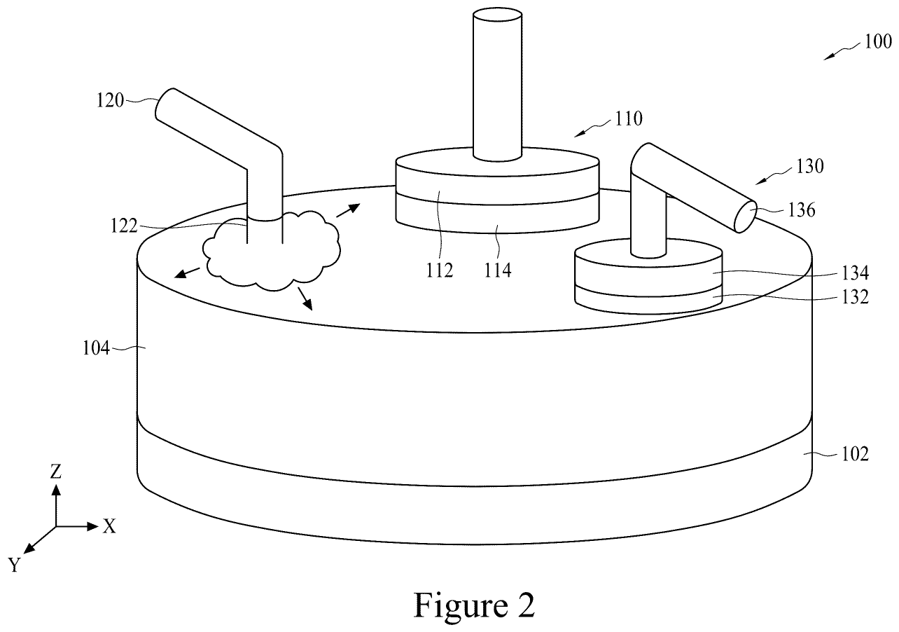

FIG. 2 is a perspective view of a CMP apparatus 100 in accordance with some embodiments. The CMP apparatus 100 may be referred to as a polishing station. The CMP apparatus 100 includes a platen 102 and a polishing pad 104 attached to an upper surface of the platen 102. The platen 102 may be configured to rotate the polishing pad 104 during a CMP process. As will be discussed in detail below, the polishing pad 104 may include a bulk substrate, protrusions formed on the bulk substrate, and grooves formed on the bulk substrate adjacent the protrusions. The polishing pad 104 may be formed of polymer materials, such as polyurethanes (PU), acrylate polymers (acrylics), modified polyurethanes, modified acrylate polymers, combinations thereof, or the like.

A polisher head 110, which includes a carrier 112 and a retainer ring 114, is placed on the polishing pad 104 and holds the wafer 300 in contact with the polishing pad 104 during the CMP process. The retainer ring 114 may be mounted to the carrier 112 using mechanical fasteners, e.g., screws or any other suitable attachment means. During the CMP process, a workpiece (e.g., the wafer 300, not separately illustrated in FIG. 2) is placed on the carrier 112 (e.g., on a lower surface of the carrier 112) within the retainer ring 114. The retainer ring 114 may have an annular shape, with a hollow center in which the workpiece is placed. The workpiece is placed in the center of the retainer ring 114 such that the retainer ring 114 holds the workpiece in place during the CMP process. The workpiece is positioned such that the layer to be polished 304 faces downward towards the polishing pad 104. The carrier 112 is configured to apply a downward force or pressure urging the workpiece into contact with the polishing pad 104. The polisher head 110 is configured to rotate the workpiece on the polishing pad 104 during the CMP process. The polisher head 110 may be configured to rotate the workpiece and the platen 102 may be configured to rotate the polishing pad 104 in a same direction or opposite directions. In some embodiments, the platen 102 is configured to rotate the polishing pad 104 during the CMP process, and the workpiece is not rotated.

A slurry dispenser 120 may be provided on the polishing pad 104 to deposit a slurry 122 onto the polishing pad 104. The platen 102 is configured to rotate the polishing pad 104, which causes the slurry 122 to be distributed between the workpiece and the polishing pad 104 through a plurality of grooves (not separately illustrated) in the retainer ring 114. The grooves may extend from an outer sidewall of the retainer ring 114 to an inner sidewall of the retainer ring 114. The composition of the slurry 122 may be dependent upon the types of materials present in the layer to be polished 304 that are desired to be polished or removed. In general, the slurry 122 may include a reactant, an abrasive, a surfactant, and a solvent. The reactant may be a chemical, such as an oxidizing agent, a reducing agent, or the like, which will chemically react with a material of the workpiece in order to assist the polishing pad 104 in abrading/removing material. The abrasive may include any suitable particulate that, in conjunction with the polishing pad 104, is configured to polish/planarize the workpiece. The surfactant may be utilized to help disperse the reactant and the abrasive within the slurry 122, and to prevent (or otherwise reduce) the abrasive from agglomerating during the CMP process. A remaining portion of the slurry 122 may include the solvent that may be utilized to combine the reactant, the abrasive, and the surfactant, and allow the mixture to be moved and dispersed onto the polishing pad 104.

A pad conditioner 130 may be provided on the polishing pad 104 to refresh the polishing pad 104. The pad conditioner 130 may include a pad conditioner pad 132 attached to a pad conditioner head 134. The pad conditioner head 134 may be configured to rotate the pad conditioner pad 132 on the surface of the polishing pad 104. The pad conditioner head 134 may be configured to rotate the pad conditioner pad 132 and the platen 102 may be configured to rotate the polishing pad 104 in a same direction or opposite directions. In some embodiments, the platen 102 is configured to rotate the polishing pad 104 during the CMP process, and the pad conditioner pad 132 is not rotated. In some embodiments, the pad conditioner pad 132 is attached to the pad conditioner head 134 using mechanical fasteners, e.g., screws or any other suitable attachment means. A pad conditioner arm 136 is attached to the pad conditioner head 134, and is configured to move the pad conditioner head 134 and the pad conditioner pad 132 in a sweeping motion across the polishing pad 104. In some embodiments, the pad conditioner pad 132 comprises a substrate over which an array of abrasive particles is bonded using, for example, electroplating. The pad conditioner pad 132 removes built-up wafer debris and excess slurry from the polishing pad 104 during CMP processing. In some embodiments, the pad conditioner pad 132 acts as an abrasive for the polishing pad 104 to create a desired texture (such as, for example, grooves, or the like) against which the workpiece may be polished.

In the embodiment illustrated in FIG. 2, the CMP apparatus 100 includes a single polisher head (e.g., the polisher head 110) and a single polishing pad (e.g., the polishing pad 104). In some embodiments, a CMP apparatus 100 may include multiple polisher heads and/or multiple polishing pads. In embodiments in which a CMP apparatus 100 includes multiple polisher heads and a single polishing pad, multiple workpieces (e.g., the wafers 300) may be polished at a same time. In embodiments in which a CMP apparatus 100 includes a single polisher head and multiple polishing pads, a CMP process may be a multi-step process, with each of the polishing pads having a different abrasiveness. In such embodiments, a first polishing pad may be used for bulk material removal from a workpiece, a second polishing pad may be used for global planarization of the workpiece, and a third polishing pad may be used to buff a surface of the workpiece.

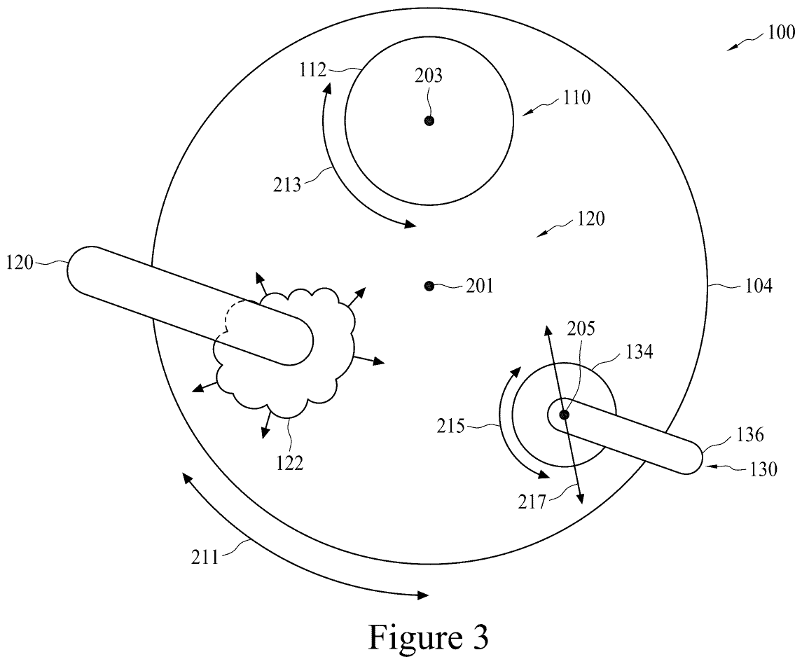

FIG. 3 illustrates a top-down view of the CMP apparatus 100 in accordance with some embodiments. The platen 102 is configured to rotate the polishing pad 104 in a clockwise or a counter-clockwise direction, as indicated by a double-headed arrow 211, around an axis extending through a centrally-disposed point 201, which is a center point of the platen 102. The polisher head 110 is configured to rotate in a clockwise or a counter-clockwise direction, as indicated by a double-headed arrow 213, around an axis extending through a centrally-disposed point 203, which is a center point of the carrier 112. The axis through point 203 may be parallel to the axis through point 201. The axis through point 203 may be spaced apart from the axis through point 201. In some embodiments, the pad conditioner head 134 is configured to rotate in a clockwise or a counter-clockwise direction, as indicated by a double-headed arrow 215, around an axis extending through a centrally-disposed point 205, which is a center point of the pad conditioner head 134. The axis through point 205 may be parallel to the axis through point 201. The pad conditioner arm 136 is configured to move the pad conditioner head 134 in an effective arc during the CMP process, as indicated by a double-headed arrow 217.

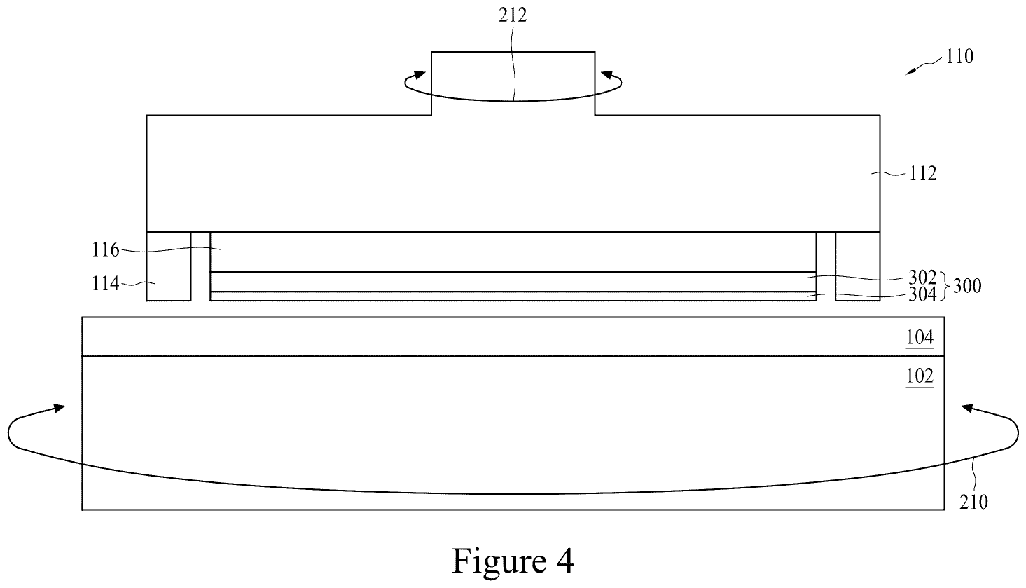

FIG. 4 illustrates a cross-sectional view of the polisher head 110 on the polishing pad 104 and the platen 102 in accordance with some embodiments. In some embodiments, the carrier 112 incudes a membrane 116 configured to interface with a wafer 300 during a CMP process. In some embodiments, the CMP apparatus 100 includes a vacuum system (not separately illustrated) coupled to the polisher head 110. The membrane 116 may be configured to pick up and hold the wafer 300 against the membrane 116 using vacuum suction from the vacuum system. The membrane 116 may form an enclosed space alone or in combination with a lower surface of the carrier 112. During the CMP process, a pressure (e.g., an interior pressure of the membrane 116) within the enclosed space may be maintained at a pre-determined level, such that the membrane 116 applies a down-force to the wafer 300 against the polishing pad 104. By adjusting the pressure, the down-force applied by the membrane 116 during the CMP process may be adjusted. The membrane 116 may include a plurality of zones, which apply different down-forces by being pressurized to different pressures, which improves the uniformity of the polishing of the wafer 300. Using the polishing pad 104, including improvements discussed in detail below, improves the uniformity of the polishing of the wafer 300 and reduces the need for different down-forces to be applied to the wafer 300 by the membrane 116.

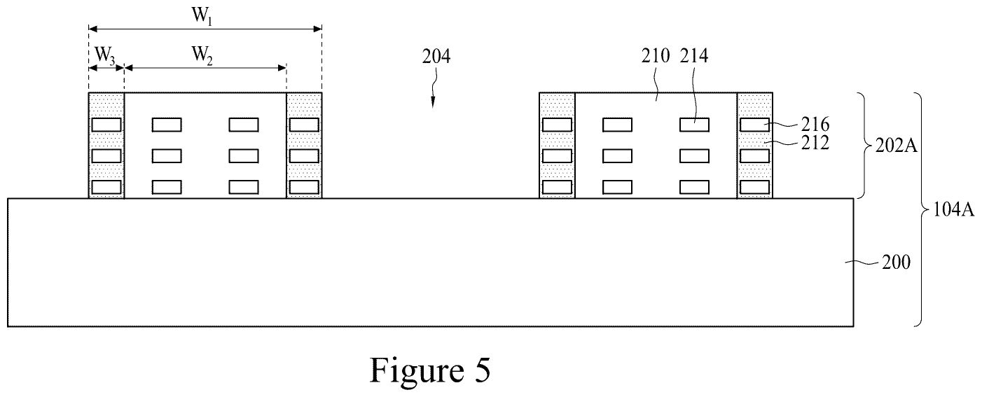

FIG. 5 illustrates a cross-sectional view of a polishing pad 104A. As illustrated in FIG. 5, the polishing pad 104A includes a polishing pad substrate 200, protrusions 202A on the polishing pad substrate 200, and grooves 204 between adjacent ones of the protrusions 202A. The protrusions 202A remove polished material from the wafer 300 and planarize excess materials of the wafer 300 (e.g., overburden), while the grooves 204 distribution the slurry 122 across the surface of the layer to be polished 304. The protrusions 202A may include a first material 210 and a second material 212. First pores 214 are provided in the first material 210 and second pores 216 are provided in the second material 212. Each of the polishing pad substrate 200, the first material 210, and the second material 212 may be formed of polymer materials, such as polyurethanes (PU), acrylate polymers (acrylics), hollow-containing polymer materials, modified polyurethanes, modified acrylate polymers, combinations thereof, or the like.

Central portions of the protrusions 202A are formed from the first material 210, and peripheral portions of the protrusions 202A are formed from the second material 212. In the embodiment of FIG. 5, the first material 210 and the second material 212 are formed of materials having different hardnesses. In some embodiments, the first material 210 has a hardness greater than a hardness of the second material 212. A ratio of the hardness of the second material 212 to the hardness of the first material 210 may be in a range from about 0.05 to about 0.95. As a result of the hardness of the second material 212 being less than the hardness of the first material 210, the second material 212 may have a compressibility greater than a compressibility of the first material 210. A ratio of the widths W₂ of the first material 210 to the widths W₁ of the protrusions 202A may be in a range from about 0.10 to about 0.988, and a ratio of the widths W₃ of the second material 212 to the widths W₁ of the protrusions 202A may be in a range from about 0.001 to about 0.45.

The first material 210 and the second material 212 have the same sizes and densities of the first pores 214 and the second pores 216, respectively. The first pores 214 and the second pores 216 may comprise hollow portions formed in polymer materials that are included in the first material 210 and the second material 212, respectively. The size of the first pores 214 and the second pores 216 may be determined based on the specific polymers that are included in the first material 210 and the second material 212. The density of the first pores 214 and the second pores 216 may be determined based on the number of polymers that are included in the first material 210 and the second material 212. Although the embodiment of FIG. 5 is illustrated as including the first material 210 and the second material 212, which have different hardnesses; in some embodiments, the protrusions 202A may include three or more different materials, each having a different hardness.

Corners of the protrusions 202A may cause scratch defects in the wafer 300, due to sharp edges of the protrusions 202A. This may lead to pattern failures and reliability issues. Providing the protrusions 202A including the second material 212, which is softer than the first material 210, in peripheral regions of the protrusions 202A (e.g., in corners/edges of the protrusions 202A) reduces scratching of the wafer 300. Providing the first material 210, which is harder than the second material 212, in central regions of the protrusions 202A improves the abrasiveness of the polishing pad 104A. In some embodiments, the polishing pad 104A may have reduced circuit failures, reduced device defects, improved electrical characteristics for the wafer 300, increased chip yield, and reduced downtime for the CMP apparatus 100.

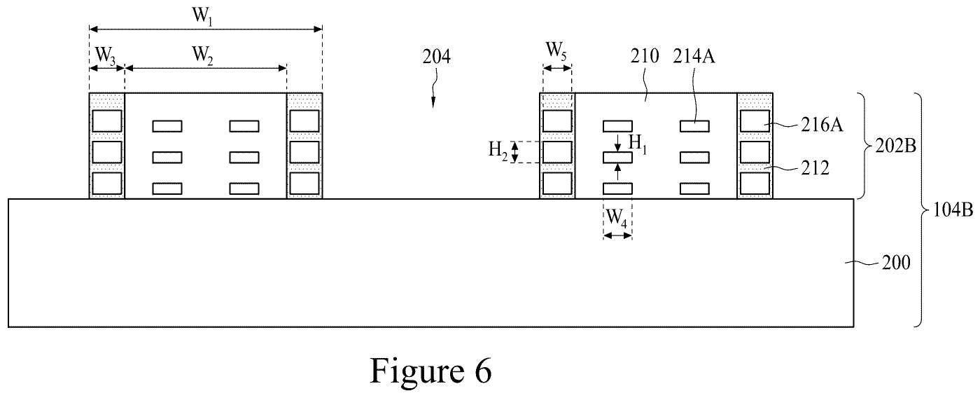

FIG. 6 illustrates a cross-sectional view of a polishing pad 104B. As illustrated in FIG. 6, the polishing pad 104B includes a polishing pad substrate 200, protrusions 202B on the polishing pad substrate 200, and grooves 204 between adjacent ones of the protrusions 202B. The protrusions 202B may include a first material 210 and a second material 212. First pores 214A are provided in the first material 210 and second pores 216A are provided in the second material 212. Each of the polishing pad substrate 200, the first material 210, and the second material 212 may be formed of polymer materials, such as polyurethanes (PU), acrylate polymers (acrylics), hollow-containing polymer materials, modified polyurethanes, modified acrylate polymers, combinations thereof, or the like.

Central portions of the protrusions 202B are formed from the first material 210, and peripheral portions of the protrusions 202B are formed from the second material 212. In the embodiment of FIG. 6, the first pores 214A formed in the first material 210 and the second pores 216A formed in the second material 212 have different sizes. In some embodiments, the second pores 216A formed in the second material 212 are larger than the first pores 214A formed in the first material 210. The first pores 214A may have heights H₁ in a range from about 1 μm to about 500 μm and widths W₄ in a range from about 1 μm to about 500 μm, and the second pores 216A may have heights H₂ in a range from about 1.1 μm to about 2000 μm and widths W₅ in a range from about 1.1 μm to about 2000 μm. As a result of the different pore sizes in the first material 210 and the second material 212, the first material 210 may have a greater hardness than the second material 212. A ratio of the hardness of the second material 212 to the hardness of the first material 210 may be in a range from about 0.05 to about 0.95. As a result of the hardness of the second material 212 being less than the hardness of the first material 210, the second material 212 may have a compressibility greater than a compressibility of the first material 210. A ratio of the widths W₂ of the first material 210 to the widths W₁ of the protrusions 202B may be in a range from about 0.10 to about 0.988, and a ratio of the widths W₃ of the second material 212 to the widths W₁ of the protrusions 202B may be in a range from about 0.001 to about 0.45.

The first material 210 and the second material 212 may be formed of the same materials, except that the first material 210 and the second material 212 include hollow-containing polymer materials having different pore sizes. For example, the first material 210 may include first hollow-containing polymer materials having first volumes and the second material 212 may include second hollow-containing polymer materials having second volumes greater than the first volumes. The first pores 214A and the second pores 216A may comprise hollow portions formed in polymer materials that are included in the first material 210 and the second material 212, respectively. The size of the first pores 214A and the second pores 216A may be determined based on the specific polymers that are included in the first material 210 and the second material 212. The density of the first pores 214A and the second pores 216A may be determined based on the number of polymers that are included in the first material 210 and the second material 212. Although the embodiment of FIG. 6 is illustrated as including the first pores 214A in the first material 210 and the second pores 216A in the second material 212, which have different pore sizes; in some embodiments, the protrusions 202B may include three or more different materials with pores of different pore sizes.

Corners of the protrusions 202B may cause scratch defects in the wafer 300, due to sharp edges of the protrusions 202B. This may lead to pattern failures and reliability issues. Providing the protrusions 202B including the second material 212, which is softer than the first material 210 (e.g., due to the second pores 216A having larger pore sizes than the first pores 214A), in peripheral regions of the protrusions 202B (e.g., in corners/edges of the protrusions 202B) reduces scratching of the wafer 300. Providing the first material 210, which is harder than the second material 212, in central regions of the protrusions 202B improves the abrasiveness of the polishing pad 104B. In some embodiments, the polishing pad 104B may have reduced circuit failures, reduced device defects, improved electrical characteristics for the wafer 300, increased chip yield, and reduced downtime for the CMP apparatus 100.

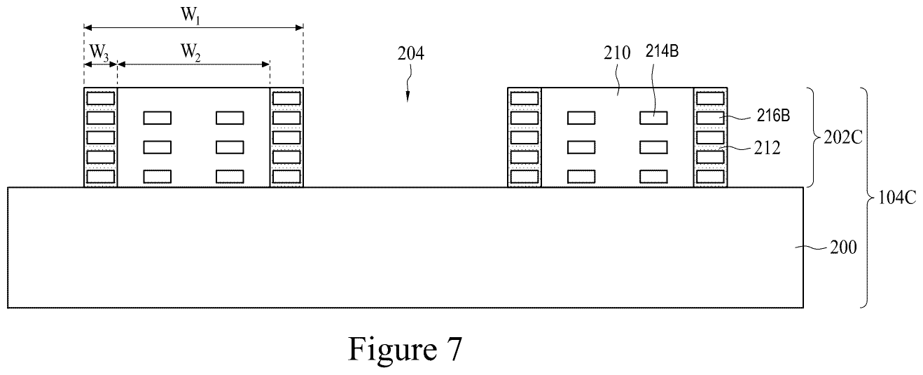

FIG. 7 illustrates a cross-sectional view of a polishing pad 104C. As illustrated in FIG. 7, the polishing pad 104C includes a polishing pad substrate 200, protrusions 202C on the polishing pad substrate 200, and grooves 204 between adjacent ones of the protrusions 202C. The protrusions 202C may include a first material 210 and a second material 212. First pores 214B are provided in the first material 210 and second pores 216B are provided in the second material 212. Each of the polishing pad substrate 200, the first material 210, and the second material 212 may be formed of polymer materials, such as polyurethanes (PU), acrylate polymers (acrylics), hollow-containing polymer materials, modified polyurethanes, modified acrylate polymers, combinations thereof, or the like.

Central portions of the protrusions 202C are formed from the first material 210, and peripheral portions of the protrusions 202C are formed from the second material 212. In the embodiment of FIG. 7, the first material 210 and the second material 212 include the first pores 214B and the second pores 216B, respectively, with different pore densities (e.g., volume of pores per total volume of the pores and the surrounding material). In some embodiments, the second pores 216B formed in the second material 212 have a greater pore density than the first pores 214A formed in the first material 210. The first pores 214B may have a pore density in the first material 210 in a range from about 0.00 to about 0.40. The second pores 216B may have a pore density in the second material 212 in a range from about 0.01 to about 0.80. As a result of the different pore densities in the first material 210 and the second material 212, the first material 210 may have a greater hardness than the second material 212. A ratio of the hardness of the second material 212 to the hardness of the first material 210 may be in a range from about 0.05 to about 0.95. As a result of the hardness of the second material 212 being less than the hardness of the first material 210, the second material 212 may have a compressibility greater than a compressibility of the first material 210. A ratio of the widths W₂ of the first material 210 to the widths W₁ of the protrusions 202C may be in a range from about 0.10 to about 0.988, and a ratio of the widths W₃ of the second material 212 to the widths W₁ of the protrusions 202C may be in a range from about 0.001 to about 0.45.

The first material 210 and the second material 212 may be formed of the same materials, except that the first material 210 and the second material 212 include hollow-containing polymer materials having different pore densities. The first pores 214B and the second pores 216B may comprise hollow portions formed in polymer materials that are included in the first material 210 and the second material 212, respectively. The densities of the first pores 214A and the second pores 216A may be determined based on the amount of the hollow-containing polymer materials that are included in the first material 210 and the second material 212. Although the embodiment of FIG. 7 is illustrated as including the first pores 214B in the first material 210 and the second pores 216B in the second material 212, which have different pore densities; in some embodiments, the protrusions 202C may include three or more different materials with pores of different pore sizes.

Corners of the protrusions 202C may cause scratch defects in the wafer 300, due to sharp edges of the protrusions 202C. This may lead to pattern failures and reliability issues. Providing the protrusions 202C including the second material 212, which is softer than the first material 210 (e.g., due to the second pores 216B having larger pore densities than the first pores 214B), in peripheral regions of the protrusions 202C (e.g., in corners/edges of the protrusions 202C) reduces scratching of the wafer 300. Providing the first material 210, which is harder than the second material 212, in central regions of the protrusions 202C improves the abrasiveness of the polishing pad 104B. In some embodiments, the polishing pad 104B may have reduced circuit failures, reduced device defects, improved electrical characteristics for the wafer 300, increased chip yield, and reduced downtime for the CMP apparatus 100.

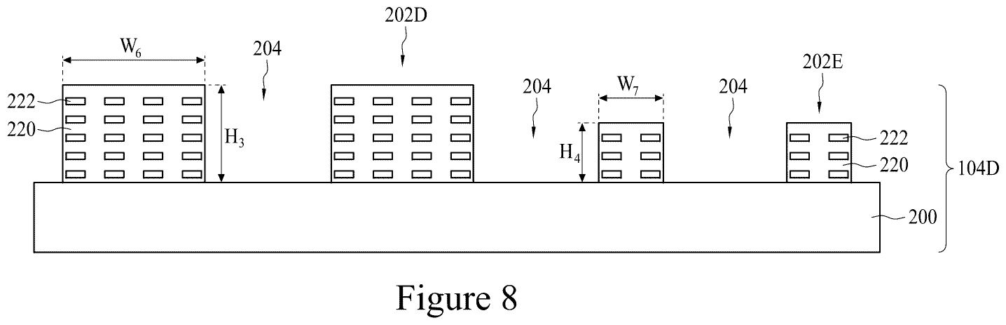

FIG. 8 illustrates a cross-sectional view of a polishing pad 104D. As illustrated in FIG. 8, the polishing pad 104D includes a polishing pad substrate 200, first protrusions 202D and second protrusions 202E on the polishing pad substrate 200, and grooves 204 between adjacent ones of the first protrusions 202D and the second protrusions 202E. The first protrusions 202D and the second protrusions 202E may include a material 220 with pores 222 being provided in the material 220. The polishing pad substrate 200 and the material 220 may be formed of polymer materials, such as polyurethanes (PU), acrylate polymers (acrylics), hollow-containing polymer materials, modified polyurethanes, modified acrylate polymers, combinations thereof, or the like.

In the embodiment of FIG. 8, the first protrusions 202D and the second protrusions 202E are formed with different heights and widths. The heights H₃ of the first protrusions 202D and the heights H₄ of the second protrusions 202E may be in a range from about 20 μm to about 5000 μm. A ratio of a difference of the heights H₃ and the heights H₄ to the heights H₃ may be in a range from about 0.30 to about 0.90. The widths W₆ of the first protrusions 202D and the widths W₇ of the second protrusions 202E may be in a range from about 1 μm to about 5000 μm. A ratio of a difference of the widths W₆ and the widths W₇ to the widths W₆ may be in a range from about 0.20 to about 0.90.

Providing the first protrusions 202D and the second protrusions 202E with different heights and widths changes the surface structure of the polishing pad 104D, and may be used to improve thickness control for the wafer 300 polished by the CMP process. The different sized first protrusions 202D and second protrusions 202E may be used to provide a more even distribution of the slurry 122 across the surface of the polishing pad 104D, and specifically between the polishing pad 104D and the wafer 300. This allows for less of the slurry 122 to be used and decreases costs, improves within-wafer thickness uniformity from polishing wafers 300, allows for more even zone-to-zone down-force settings to be applied from the membrane 116 to the wafers 300, and improves wafer-to-wafer polishing uniformity. The more even polishing resulting from including the first protrusions 202D and the second protrusions 202E in the polishing pad 104D reduces device defects and improves device performance for devices formed on wafers 300 polished by the polishing pad 104D.

The first protrusions 202D and the second protrusions 202E may be formed of the same materials, with the same pore sizes, and the same pore densities. However, in some embodiments, the first protrusions 202D and the second protrusions 202E may include first and second materials formed of different materials, with different pore sizes, and/or with different pore densities, according to any of the embodiments discussed with respect to FIGS. 5 through 7.

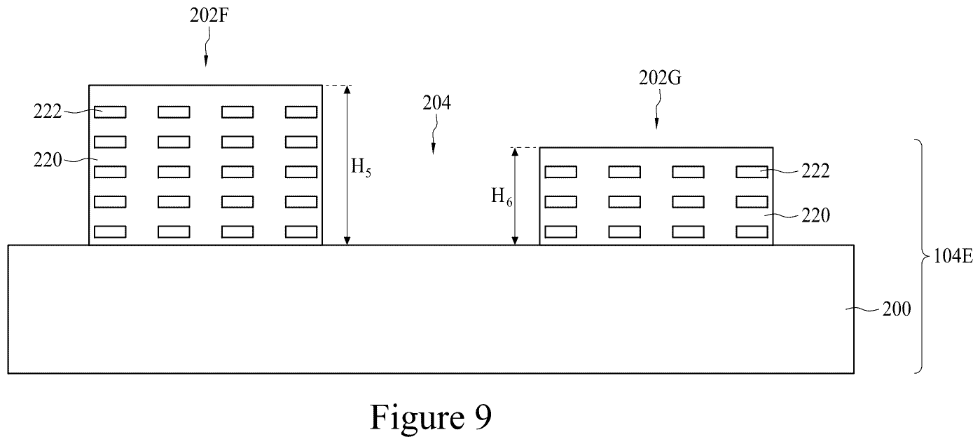

FIG. 9 illustrates a cross-sectional view of a polishing pad 104E. As illustrated in FIG. 9, the polishing pad 104E includes a polishing pad substrate 200, first protrusions 202F and second protrusions 202G on the polishing pad substrate 200, and grooves 204 between adjacent ones of the first protrusions 202F and the second protrusions 202G. The first protrusions 202F and the second protrusions 202G may include a material 220 with pores 222 being provided in the material 220. The polishing pad substrate 200 and the material 220 may be formed of polymer materials, such as polyurethanes (PU), acrylate polymers (acrylics), hollow-containing polymer materials, modified polyurethanes, modified acrylate polymers, combinations thereof, or the like.

In the embodiment of FIG. 9, the first protrusions 202F and the second protrusions 202G are formed with different heights. The heights H₅ of the first protrusions 202F and the heights H₆ of the second protrusions 202G may be in a range from about 20 μm to about 5000 μm. A ratio of a difference of the heights H₅ and the heights H₆ to the heights H₅ may be in a range from about 0.30 to about 0.90.

Providing the first protrusions 202F and the second protrusions 202G with different heights changes the surface structure of the polishing pad 104E, and may be used to improve thickness control for the wafer 300 polished by the CMP process. The different sized first protrusions 202F and second protrusions 202G may be used to provide a more even distribution of the slurry 122 across the surface of the polishing pad 104E, and specifically between the polishing pad 104E and the wafer 300. This allows for less of the slurry 122 to be used and decreases costs, improves within-wafer thickness uniformity from polishing wafers 300, allows for more even zone-to-zone down-force settings to be applied from the membrane 116 to the wafers 300, and improves wafer-to-wafer polishing uniformity. The more even polishing resulting from including the first protrusions 202F and the second protrusions 202G in the polishing pad 104E reduces device defects and improves device performance for devices formed on wafers 300 polished by the polishing pad 104E.

The first protrusions 202F and the second protrusions 202G may be formed of the same materials, with the same pore sizes, and the same pore densities. However, in some embodiments, the first protrusions 202F and the second protrusions 202G may include first and second materials formed of different materials, with different pore sizes, and/or with different pore densities, according to any of the embodiments discussed with respect to FIGS. 5 through 7.

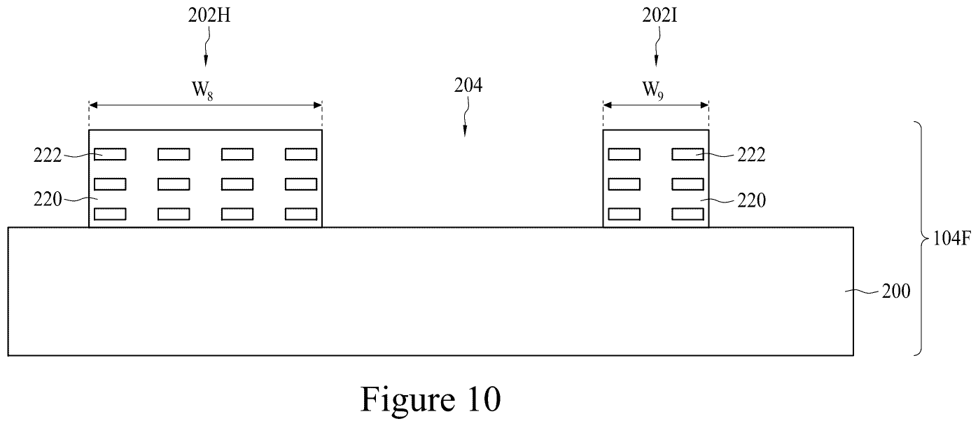

FIG. 10 illustrates a cross-sectional view of a polishing pad 104F. As illustrated in FIG. 10, the polishing pad 104F includes a polishing pad substrate 200, first protrusions 202H and second protrusions 202I on the polishing pad substrate 200, and grooves 204 between adjacent ones of the first protrusions 202H and the second protrusions 202I. The first protrusions 202H and the second protrusions 202I may include a material 220 with pores 222 being provided in the material 220. The polishing pad substrate 200 and the material 220 may be formed of polymer materials, such as polyurethanes (PU), acrylate polymers (acrylics), hollow-containing polymer materials, modified polyurethanes, modified acrylate polymers, combinations thereof, or the like.

In the embodiment of FIG. 10, the first protrusions 202H and the second protrusions 202I are formed with different widths. The widths W₈ of the first protrusions 202H and the widths W₉ of the second protrusions 202I may be in a range from about 1 μm to about 5000 μm. A ratio of a difference of the widths W₈ and the widths W₉ to the widths W₈ may be in a range from about 0.20 to about 0.90.

Providing the first protrusions 202H and the second protrusions 202I with different widths changes the surface structure of the polishing pad 104F, and may be used to improve thickness control for the wafer 300 polished by the CMP process. The different sized first protrusions 202H and second protrusions 202I may be used to provide a more even distribution of the slurry 122 across the surface of the polishing pad 104F, and specifically between the polishing pad 104F and the wafer 300. This allows for less of the slurry 122 to be used and decreases costs, improves within-wafer thickness uniformity from polishing wafers 300, allows for more even zone-to-zone down-force settings to be applied from the membrane 116 to the wafers 300, and improves wafer-to-wafer polishing uniformity. The more even polishing resulting from including the first protrusions 202H and the second protrusions 202I in the polishing pad 104F reduces device defects and improves device performance for devices formed on wafers 300 polished by the polishing pad 104F.

The first protrusions 202H and the second protrusions 202I may be formed of the same materials, with the same pore sizes, and the same pore densities. However, in some embodiments, the first protrusions 202H and the second protrusions 202I may include first and second materials formed of different materials, with different pore sizes, and/or with different pore densities, according to any of the embodiments discussed with respect to FIGS. 5 through 7.

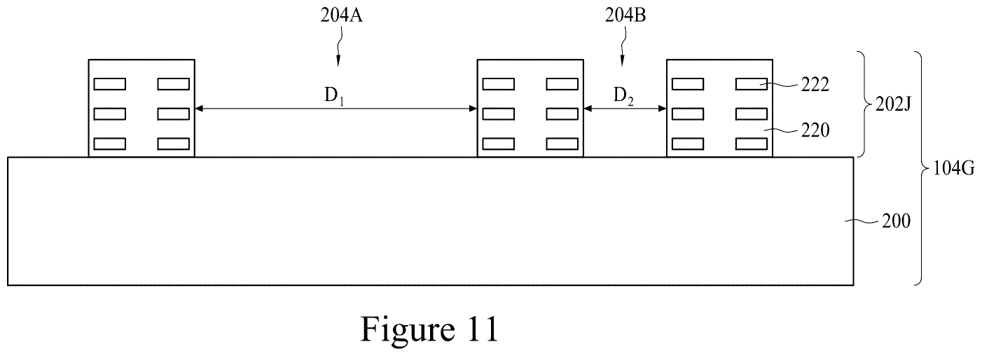

FIG. 11 illustrates a cross-sectional view of a polishing pad 104G. As illustrated in FIG. 11, the polishing pad 104G includes a polishing pad substrate 200, protrusions 202J on the polishing pad substrate 200, and first grooves 204A and second grooves 204B between adjacent ones of the protrusions 202J. The protrusions 202J may include a material 220 with pores 222 being provided in the material 220. The polishing pad substrate 200 and the material 220 may be formed of polymer materials, such as polyurethanes (PU), acrylate polymers (acrylics), hollow-containing polymer materials, modified polyurethanes, modified acrylate polymers, combinations thereof, or the like.

In the embodiment of FIG. 11, the first grooves 204A and the second grooves 204B between the protrusions 202J are formed with different widths such that the protrusions 202J are space apart by different distances. The first grooves 204A may separate adjacent protrusions 202J by distances D₁ and the second grooves 204B may separate adjacent protrusions 202J by distances D₂. The distances D₁ of the first grooves 204A and the distances D₂ of the second grooves 204B may be in a range from about 1 μm to about 5000 μm. A ratio of a difference of the distances D₁ and the distances D₂ to the distances D₁ may be in a range from about 0.20 to about 0.90.

Providing the first grooves 204A and the second grooves 204B with different widths changes the surface structure of the polishing pad 104G, and may be used to improve thickness control for the wafer 300 polished by the CMP process. The different sized first grooves 204A and the second grooves 204B may be used to provide a more even distribution of the slurry 122 across the surface of the polishing pad 104G, and specifically between the polishing pad 104G and the wafer 300. This allows for less of the slurry 122 to be used and decreases costs, improves within-wafer thickness uniformity from polishing wafers 300, allows for more even zone-to-zone down-force settings to be applied from the membrane 116 to the wafers 300, and improves wafer-to-wafer polishing uniformity. The more even polishing resulting from including the first grooves 204A and the second grooves 204B in the polishing pad 104G reduces device defects and improves device performance for devices formed on wafers 300 polished by the polishing pad 104G.

The protrusions 202J may be formed of the same materials, with the same pore sizes, and the same pore densities. However, in some embodiments, the protrusions 202J may include first and second materials formed of different materials, with different pore sizes, and/or with different pore densities, according to any of the embodiments discussed with respect to FIGS. 5 through 7.

FIGS. 5 through 11 illustrate various embodiments in which protrusions are formed with varying materials GH (e.g., FIG. 5), varying pore sizes GPS (e.g., FIG. 6), varying pore densities GPD (e.g., FIG. 7), varying protrusion sizes (e.g., FIG. 8), varying protrusion heights GAH (e.g., FIG. 9), varying protrusion widths GAW (e.g., FIG. 10), and varying protrusion spacing GAD (e.g., FIG. 11). The features from any individual embodiment may be used individually, or combined with the features from others of the embodiments of FIGS. 5 through 11. For example, the protrusions may include varying materials and pore sizes; varying materials and pore densities; varying materials and protrusion heights; varying materials and protrusion widths; varying materials and protrusion spacing; varying pore sizes and pore densities; varying pore sizes and protrusion heights; varying pore sizes and protrusion widths; varying pore sizes and protrusion spacing; varying pore densities and protrusion heights; varying pore densities and protrusion widths; varying pore densities and protrusion spacing; varying protrusion heights and protrusion widths; varying protrusion heights and protrusion spacing; and varying protrusion widths and protrusion spacing. In some embodiments, the protrusions may include varying materials, pore sizes, and pore densities; varying materials, pore sizes, and protrusion heights; varying materials, pore sizes, and protrusion widths; varying materials, pore sizes, and protrusion spacing; varying materials, pore densities, and protrusion heights; varying materials, pore densities, and protrusion widths; varying materials, pore densities, and protrusion spacing; varying materials, protrusion heights, and protrusion widths; varying materials, protrusion heights, and protrusion spacing; varying materials, protrusion widths, and protrusion spacing; varying pore size, pore density, and protrusion heights; varying pore size, pore density, and protrusion widths; varying pore size, pore density, and protrusion spacing; varying pore size, protrusion heights, and protrusion widths; varying pore size, protrusion heights, and protrusion spacing; varying pore size, protrusion widths, and protrusion spacing; varying pore density, protrusion heights, and protrusion widths; varying pore density, protrusion heights, and protrusion spacing; varying pore density, protrusion widths, and protrusion spacing; and varying protrusion heights, protrusion widths, and protrusion spacing. In some embodiments, the protrusions may include varying materials, pore sizes, pore densities, and protrusion heights; varying materials, pore sizes, pore densities, and protrusion widths; varying materials, pore sizes, pore densities, and protrusion spacing; varying materials, pore sizes, protrusion heights, and protrusion widths; varying materials, pore sizes, protrusion heights, and protrusion spacing; varying materials, pore sizes, protrusion widths, and protrusion spacing; varying materials, pore densities, protrusion heights, and protrusion widths; varying materials, pore densities, protrusion heights, and protrusion spacing; varying materials, pore densities, protrusion widths, and protrusion spacing; varying materials, protrusion heights, protrusion widths, and protrusion spacing; varying pore sizes, pore densities, protrusion heights, and protrusion widths; varying pore sizes, pore densities, protrusion heights, and protrusion spacing; varying pore sizes, pore densities, protrusion widths, and protrusion spacing; varying pore sizes, protrusion heights, protrusion widths, and protrusion spacing; and varying pore densities, protrusion heights, protrusion widths, and protrusion spacing. In some embodiments, the protrusions may include varying materials, pore sizes, pore densities, protrusion heights, and protrusion widths; varying materials, pore sizes, pore densities, protrusion heights, and protrusion spacing; varying pore sizes, pore densities, protrusion heights, protrusion widths, and protrusion spacing; varying materials, pore densities, protrusion heights, protrusion widths, and protrusion spacing; varying materials, pore sizes, protrusion heights, protrusion widths, and protrusion spacing; and varying materials, pore sizes, pore densities, protrusion widths, and protrusion spacing. In some embodiments, the protrusions may include varying materials, pore sizes, pore densities, protrusion heights, protrusion widths, and protrusion spacing.

Including combinations of features from the embodiments of FIGS. 5 through 7 and the embodiments of FIGS. 8 through 11 allows polishing pads to include benefits of the protrusions having improved material profiles (e.g., multiple hardnesses) as well as improved protrusion/groove profiles. For example, the polishing pads may cause reduced scratch defects in the wafers 300. This may reduce pattern failures and reliability issues. Providing the protrusions including materials of different hardnesses reduces scratching of the wafer 300, while providing improved abrasiveness of the polishing pads. In some embodiments, the polishing pads may have reduced circuit failures, reduced device defects, improved electrical characteristics for the wafer 300, increased chip yield, and reduced downtime for the CMP apparatus 100. Providing varying sizes of the protrusions and the grooves across the surface of the polishing pads changes the surface structures of the polishing pads, and may be used to improve thickness control for the wafer 300 polished by the CMP process. The different sized features may be used to provide a more even distribution of the slurry 122 across the surface of the polishing pads, and specifically between the polishing pads and the wafer 300. This allows for less of the slurry 122 to be used and decreases costs, improves within-wafer thickness uniformity from polishing wafers 300, allows for more even zone-to-zone down-force settings to be applied from the membrane 116 to the wafers 300, and improves wafer-to-wafer polishing uniformity. The more even polishing resulting from including the different sized features in the polishing pads reduces device defects and improves device performance for devices formed on wafers 300 polished by the polishing pads.

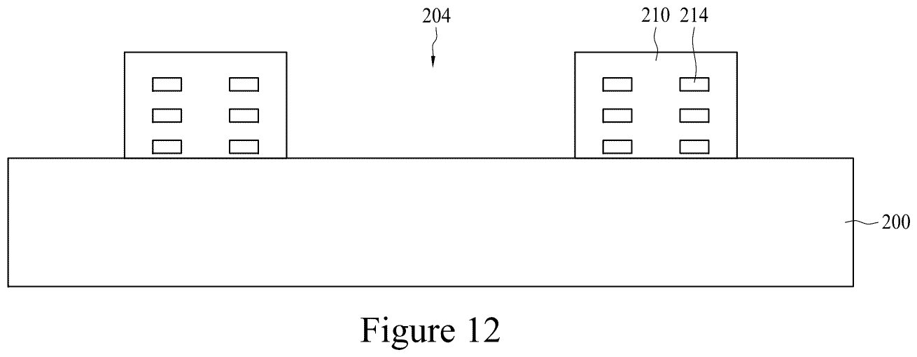

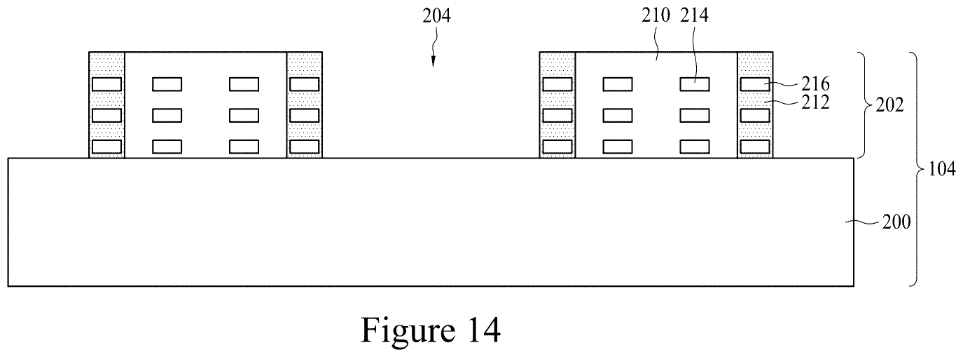

FIGS. 12 through 14 are cross-sectional views of intermediate stages in the manufacturing of polishing pads 104 (illustrated in FIG. 14), in accordance with some embodiments. In FIG. 12, first materials 210, including first pores 214, are formed on a polishing pad substrate 200. Each portion of the first materials 210 that will subsequently form a protrusion may be separated from adjacent first materials 210 by grooves 204. The polishing pad substrate 200 and the first materials 210 may be formed of polymer materials, such as polyurethanes (PU), acrylate polymers (acrylics), hollow-containing polymer materials, modified polyurethanes, modified acrylate polymers, combinations thereof, or the like. The first materials 210 may be deposited on the polishing pad substrate 200 using additive manufacturing techniques, such as 3D printing, aerosol jet printing (e.g., aerosol patterning technology), or the like. In some embodiments, the first materials 210 may be formed on the polishing pad substrate 200, or the first materials 210 and the polishing pad substrate 200 may be formed simultaneously, using molding processes. The first materials 210 and the first pores 214 may have any of the dimensions and characteristics discussed above with respect to the embodiments illustrated in FIGS. 5 through 11. Although the first materials 210 and the polishing pad substrate 200 are illustrated as being separate materials, in some embodiments, the first materials 210 may be continuous with, and formed simultaneously with the polishing pad substrate 200.

In some embodiments, the grooves 204 and the first materials 210 may be formed by subtractive manufacturing techniques. For example, a polishing pad substrate 200 may be provided, and the grooves 204 and first materials 210 may be formed in the polishing pad substrate 200 by a computer numeric control (CNC) machining process. The CNC machining process may be performed by a mechanical drill, a laser drill, etching, or the like.

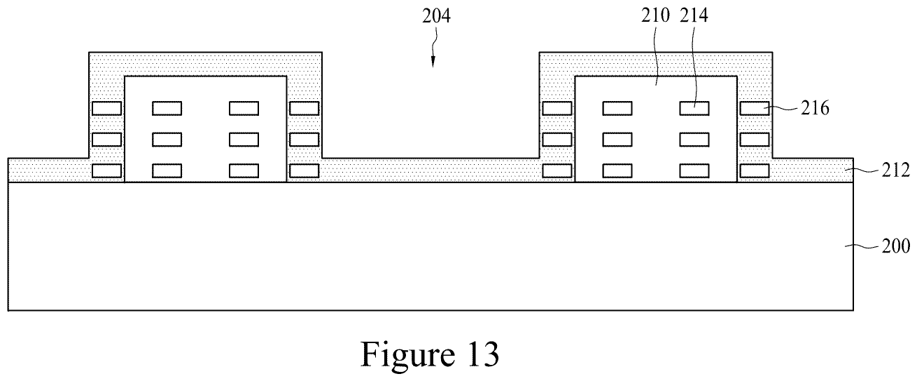

In FIG. 13, second materials 212, including second pores 216, are formed on the first materials 210 and the polishing pad substrate 200. The second materials 212 may be formed of polymer materials, such as polyurethanes (PU), acrylate polymers (acrylics), hollow-containing polymer materials, modified polyurethanes, modified acrylate polymers, combinations thereof, or the like. The second materials 212 may be deposited on the polishing pad substrate 200 using additive manufacturing techniques, such as 3D printing, aerosol jet printing, or the like. In some embodiments, the second materials 212 may be deposited by a conformal deposition process, such as chemical vapor deposition (CVD), atomic layer deposition (ALD), or the like. The second materials 212 and the second pores 216 may have any of the dimensions and characteristics discussed above with respect to the embodiments illustrated in FIGS. 5 through 11.

In FIG. 14, the second materials 212 are etched to form protrusions 202, which include portions of the first materials 210 and the second materials 212. The second materials 212 may be etched by any acceptable etch process, such as dry etching, reactive ion etching (RIE), neutral beam etching (NBE), the like, or a combination thereof. The etching may be anisotropic. Following the etching, the protrusions 202 and the grooves 204 may have any of the dimensions and characteristics discussed above with respect to the embodiments illustrated in FIGS. 5 through 11.

Using additive manufacturing techniques to form the first materials 210 and the second materials 212 of the protrusions 202 allows for the first materials 210 and the second materials 212 to be formed in desired patterns, of desired materials, and with desired pore sizes and densities, which allows the above-described benefits of the improved polishing pads 104 to be achieved. Further, using additive manufacturing techniques for forming the protrusions 202 reduces waste.

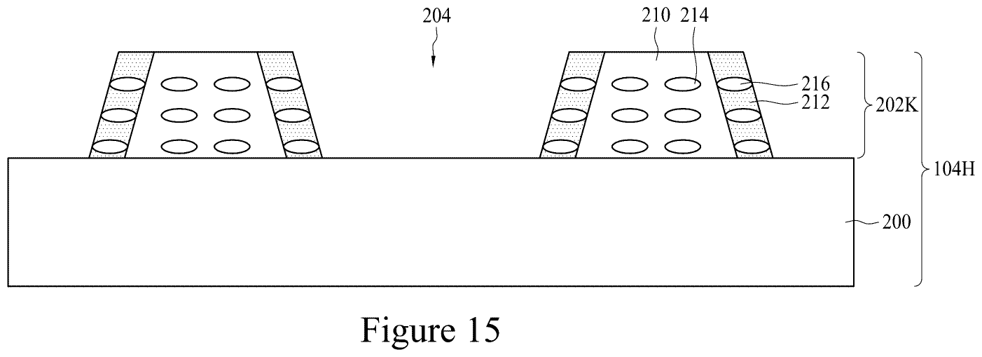

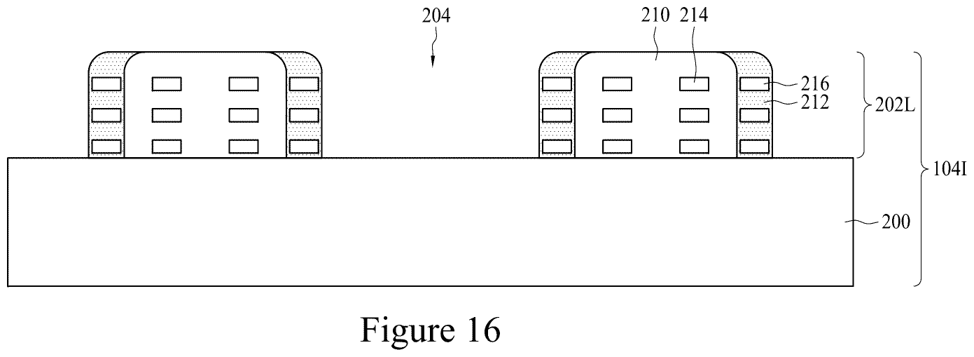

FIGS. 15 and 16 illustrate polishing pads 104H and 104I including protrusions 202K and 202L, respectively, having different cross-sectional shapes from the above-described embodiments. In the embodiment illustrated in FIG. 15, the protrusions 202K have trapezoidal shapes in a cross-sectional view. In the embodiment illustrated in FIG. 16, the protrusions 202L have rounded top corners in a cross-sectional view. Forming the protrusions with trapezoidal shapes and/or rounded top corners may further reduce the scratch defects in the wafer 300 caused by sharp edges of the protrusions (e.g., protrusions with trapezoidal shapes and/or rounded top corners have less sharp edges than protrusions with square corners). This reduces failures and reliability issues. In some embodiments, the polishing pads 104H and 104I may have reduced circuit failures, reduced device defects, improved electrical characteristics for the wafer 300, increased chip yield, and reduced downtime for the CMP apparatus 100.

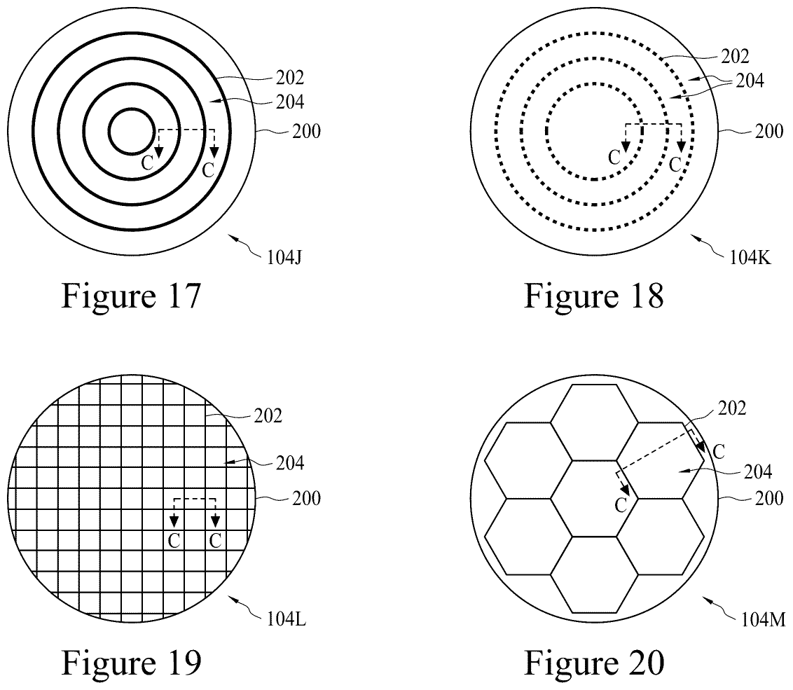

FIGS. 17 through 21 illustrate top-down views of polishing pads (e.g., polishing pads 104J, 104K, 104L, 104M, and 104N, respectively), in accordance with some embodiments. In some embodiments, regardless of the shape of the protrusions 202 in the top-down view, the cross-sectional shapes and configurations of each of the protrusions 202 in FIGS. 17 through 21 (e.g., taken along cross-section C-C in each of the FIGS. 17 through 21) may be any of the shapes and configurations discussed with respect to FIGS. 5 through 16. In FIGS. 17 through 21, the materials and the formation methods of the polishing pads 104J-104N, including the polishing pad substrates 200, the protrusions 202, and the grooves 204, may be the same as or similar to those of FIGS. 5 through 16. More specifically, the materials, pore sizes, pore densities, protrusions heights, protrusion widths, and protrusion spacing of the protrusions 202 and the grooves 204 illustrated in FIGS. 17 through 21 may be the same as or similar to those discussed with respect to FIGS. 5 through 16.

In FIG. 17, the protrusions 202 of the polishing pad 104J comprise a plurality of concentric circle-shaped structures protruding from the upper surface of the polishing pad substrate 200. The grooves 204 may also be concentric circle-shaped. Widths of the protrusions 202, heights of the protrusions 202, and/or distances between the protrusions 202 may increase from the circumference of the polishing pad substrate 200 towards the center of the polishing pad substrate 200, or from the center of the polishing pad substrate 200 towards the circumference of the polishing pad substrate 200.

In FIG. 18, the protrusions 202 of the polishing pad 104K comprise a plurality of concentric circle-shaped structures protruding from the upper surface of the polishing pad substrate 200. The grooves 204 may include concentric circle-shaped portions and portions extending through the protrusions 202 in directions perpendicular to a central axis of the polishing pad substrate 200. Widths of the protrusions 202, heights of the protrusions 202, and/or distances between the protrusions 202 may increase from the circumference of the polishing pad substrate 200 towards the center of the polishing pad substrate 200, or from the center of the polishing pad substrate 200 towards the circumference of the polishing pad substrate 200.

In FIG. 19, the protrusions 202 of the polishing pad 104L comprise a plurality of grid shaped structures protruding from the upper surface of the polishing pad substrate 200. In other words, the protrusions 202 include a first plurality of strips (e.g., rectangular prisms) that are parallel to each other and extend across the surface of the polishing pad substrate 200 along the horizontal direction of FIG. 19. The protrusions 202 further include a second plurality of strips (e.g., rectangular prisms) that are parallel to each other and extend across the surface of the polishing pad substrate 200 along a direction perpendicular to the first plurality of strips (e.g., along the vertical direction of FIG. 19). The grooves 204 are rectangular in the top-down view of FIG. 19. Widths of the protrusions 202, heights of the protrusions 202, and/or distances between the protrusions 202 may increase from the circumference of the polishing pad substrate 200 towards the center of the polishing pad substrate 200, or from the center of the polishing pad substrate 200 towards the circumference of the polishing pad substrate 200.

In FIG. 20, the protrusions 202 of the polishing pad 104M comprise a plurality of honeycomb shaped structures protruding from the upper surface of the polishing pad substrate 200. The grooves 204 are hexagonal in the top-down view of FIG. 20. Besides a hexagon, other polygon shapes, such as a triangle, a pentagon, an octagon, or the like, may be used for the protrusions 202. These and other variations are fully intended to be included within the scope of the present disclosure. Widths of the protrusions 202, heights of the protrusions 202, and/or distances between the protrusions 202 may increase from the circumference of the polishing pad substrate 200 towards the center of the polishing pad substrate 200, or from the center of the polishing pad substrate 200 towards the circumference of the polishing pad substrate 200.

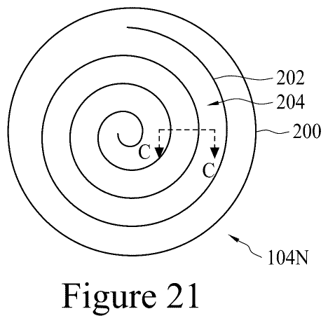

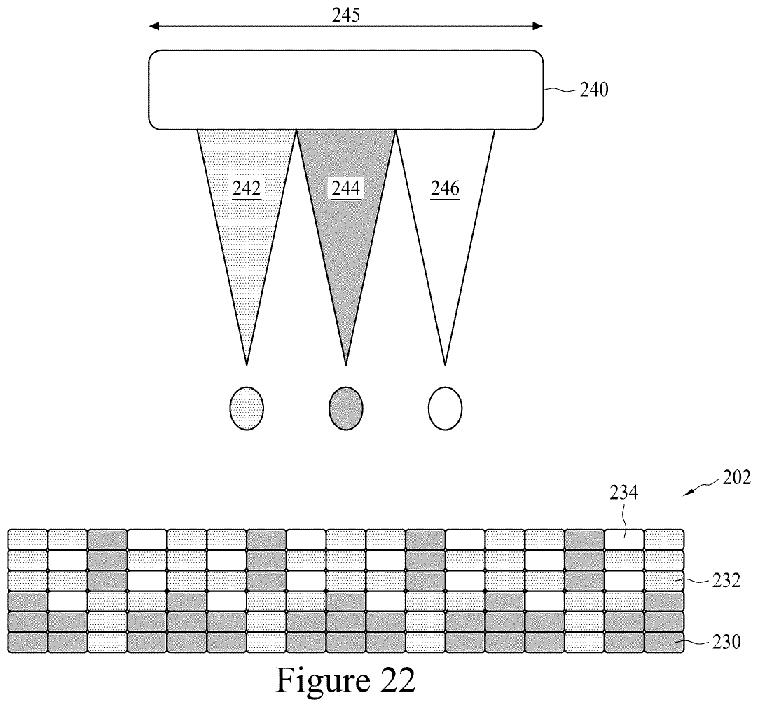

In FIG. 21, the protrusions 202 of the polishing pad 104N comprise a spiral-shaped structure protruding from the upper surface of the polishing pad substrate 200. In some embodiments, the spiral-shaped structure may extend from the center of the polishing pad substrate 200 to the circumference of the polishing pad substrate 200. Although one spiral-shaped structure is illustrated in FIG. 21, the protrusions 202 may include multiple spiral-shaped structures. Widths of the protrusions 202, heights of the protrusions 202, and/or distances between the protrusions 202 may increase from the circumference of the polishing pad substrate 200 towards the center of the polishing pad substrate 200, or from the center of the polishing pad substrate 200 towards the circumference of the polishing pad substrate 200.

FIGS. 17 through 21 are merely examples and not intended to be limiting. Other variations are possible and are fully intended to be included within the scope of the present disclosure. For example, the number of honeycomb-shaped structures, or the number of concentric circle-shaped structures may be different from what was illustrated, depending on, e.g., the size of the polishing pad substrate 200, the sizes of the protrusions 202, and the sizes of the grooves 204. Any suitable shape, size, and location of the protrusions 202 that provide pre-determined, consistent, and repeatable asperities for the polishing pads 104 may be used.

FIG. 22 illustrates a method of additively manufacturing a protrusion 202. The protrusion includes a first material 230, a second material 232, and a hollow-containing material 234. The first material 230 and the second material 232 may be formed of polymer materials, such as polyurethanes (PU), acrylate polymers (acrylics), modified polyurethanes, modified acrylate polymers, combinations thereof, or the like. In some embodiments, the first material 230 has a hardness greater than a hardness of the second material 232. A ratio of the hardness of the second material 232 to the hardness of the first material 230 may be in a range from about 0.05 to about 0.95. The hollow-containing material 234 may be formed of hollow-containing polymer materials or the like, and may form any of the pores discussed above with respect to FIGS. 5 through 21. The first material 230, the second material 232, and the hollow-containing material 234 may be deposited in desired locations by a first nozzle 242, a second nozzle 244, and a third nozzle 246 of a printer head 240. The first material 230, the second material 232, and the hollow-containing material 234 may be deposited by the printer head 240 to form any of the protrusions 202 discussed above with respect to FIGS. 5 through 21.

Embodiments may achieve advantages. For example, including protrusions in polishing pads that include varying materials, varying pore sizes, varying pore densities, varying heights, varying widths, and varying spacing allows polishing pads to include benefits of the protrusions having improved material profiles (e.g., multiple hardnesses) as well as improved protrusion/groove profiles. For example, the polishing pads may cause reduced scratch defects in wafers polished by the polishing pads. This may reduce pattern failures and reliability issues. Providing the protrusions including materials of different hardnesses reduces scratching of the wafers, while providing improved abrasiveness of the polishing pads. In some embodiments, using the polishing pads such as those described herein may yield devices having reduced circuit failures, reduced device defects, improved electrical characteristics for the wafers, and increased chip yield, while reducing downtime for CMP apparatuses using the polishing pads. Providing varying sizes of the protrusions and the grooves across the surface of the polishing pads changes the surface structures of the polishing pads, and may be used to improve thickness control for the wafers polished by CMP processes. The different sized features may be used to provide a more even distribution of slurry/CMP chemicals across the surface of the polishing pads, and specifically between the polishing pads and the wafers. This allows for less of the slurry to be used and decreases costs, improves within-wafer thickness uniformity from polishing wafers, allows for more even zone-to-zone down-force settings to be applied from a membrane to the wafers, and improves wafer-to-wafer polishing uniformity. The more even polishing resulting from including the different sized features in the polishing pads reduces device defects and improves device performance for devices formed on wafers polished by the polishing pads.

In accordance with an embodiment, a polishing pad includes a polishing pad substrate; a first protrusion on the polishing pad substrate, the first protrusion including a central region and a peripheral region surrounding the central region, and a first hardness of the central region being greater than a second hardness of the peripheral region; and a first groove adjacent a first side of the first protrusion. In an embodiment, a ratio of the second hardness to the first hardness is from 0.05 to 0.95. In an embodiment, the central region includes a first material, and the peripheral region includes a second material having a different material composition from the first material. In an embodiment, the central region includes a plurality of first pores, the peripheral region includes a plurality of second pores, and a first dimension of the first pores measured in a first direction parallel to a major surface of the polishing pad is less than a second dimension of the second pores measured in the first direction. In an embodiment, the central region includes a plurality of first pores, the peripheral region includes a plurality of second pores, and a first volume density of the first pores is less than a second volume density of the second pores. In an embodiment, the first protrusion has a first width, the central region has a second width, the peripheral region has a third width, a ratio of the second width to the first width is from 0.10 to 0.988, and a ratio of the third width to the first width is from 0.001 to 0.45. In an embodiment, the first protrusion further includes a second peripheral region surrounding the peripheral region, a third hardness of the second peripheral region is less than the second hardness of the peripheral region.

In accordance with another embodiment, a polishing pad includes a pad layer; a first polishing structure on the pad layer, the first polishing structure having a first width and a first height; and a second polishing structure on the pad layer adjacent the first polishing structure, the second polishing structure having a second width and a second height, and at least one of the first width is different from the second width or the first height is different from the second height. In an embodiment, the polishing pad further includes a third polishing structure on the pad layer adjacent the second polishing structure, the second polishing structure is separated from the first polishing structure by a first distance, and the second polishing structure is separated from the third polishing structure by a second distance different from the first distance. In an embodiment, a difference between the first distance and the second distance divided by the first distance is in a range from 0.20 to 0.90. In an embodiment, the first distance and the second distance are in a range from 1 μm to 5000 μm. In an embodiment, a difference between the first width and the second width divided by the first width is in a range from 0.20 to 0.90. In an embodiment, a difference between the first height and the second height divided by the first height is in a range from 0.30 to 0.90. In an embodiment, the first width and the second width are in a first range from 1 μm to 5000 μm, and the first height and the second height are in a second range from 20 μm to 5000 μm.

In accordance with yet another embodiment, a method of forming a polishing pad includes forming a plurality of first protrusions on a polishing pad substrate, the first protrusions including a first material having a first hardness; and forming a second material on side surfaces of the first protrusions, the second material having a second hardness different from the first hardness. In an embodiment, the first material of the first protrusions and the second material are deposited by 3D printing. In an embodiment, the first material of the first protrusions and the second material are deposited by aerosol jet printing. In an embodiment, forming the second material includes depositing the second material along top surfaces of the polishing pad substrate, top surfaces of the first protrusions, and side surfaces of the first protrusions; and etching the second material from the top surfaces of the polishing pad substrate and the top surfaces of the first protrusions. In an embodiment, the first material and the second material include a hollow-containing polymer, the hollow-containing polymer is present in the first material in a first concentration, and the hollow-containing polymer is present in the second material in a second concentration greater than the first concentration. In an embodiment, the first material includes a first hollow-containing polymer, the second material includes a second hollow-containing polymer, and a first volume of a first hollow in the first hollow-containing polymer is greater than a second volume of a second hollow in the second hollow-containing polymer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A polishing pad comprising:
a polishing pad substrate;
a first protrusion on the polishing pad substrate, wherein the first protrusion comprises a central region and a peripheral region laterally surrounding the central region, and wherein a first hardness of the central region is different than a second hardness of the peripheral region; and
a first groove adjacent a first side of the first protrusion, wherein a ratio of the second hardness to the first hardness is from 0.05 to 0.95, and wherein the central region comprises a first material, and wherein the peripheral region comprises a second material having a different material composition from the first material.
